(19) United States
(12) Patent Application Publication
(10) Pub. No.: US 2016/0284946 A1
(43) Pub. Date: Sep. 29, 2016

(54) ILLUMINANT COMPONENT

(71) Applicant: ProLight Opto Technology Corporation, TaoYuan County (TW)

(72) Inventors: Chen-Lun HSING CHEN, TaoYuan County (TW); Jung-Hao HUNG, TaoYuan County (TW); Kun-Li LIN, TaoYuan County (TW)

(21) Appl. No.: 14/669,903

(22) Filed: Mar. 26, 2015

(51) Int. Cl. H01L 33/50; H01L 33/58

(52) U.S. Cl. CPC H01L 33/50; H01L 33/58

(57) ABSTRACT

An illuminant component includes a carrier, a plurality of connecting pieces, a LED die, a first fluorescent layer, and a second fluorescent layer. The carrier includes a die-bonding area and the connecting pieces are placed on the die-bonding area. The LED die is placed on the die-bonding area and electrically connected to the connecting pieces. The first fluorescent layer placed on a top surface of the LED die includes a first light-transparent adhesive and a first phosphor powder uniformly suspended within the first light-transparent adhesive. The second fluorescent layer covering the first fluorescent layer and the LED die includes a second light-transparent adhesive and a second phosphor powder uniformly suspended within the second light-transparent adhesive. In the same quantity of the first light-transparent adhesive and the second light-transparent adhesive, the quantity of the second phosphor powder is less than that of the first phosphor powder.

### BACKGROUND OF THE INVENTION

1. Field of the Invention

The present invention relates to an illuminant component, and in particular to a light emitting diode component.

2. Description of Related Art

Reference is made to FIG. 1, which is a sectional view of a convention illuminant component. The illuminant component 1 includes a carrier 10, a light emitting diode (LED) die, and a fluorescent layer 14. The carrier 10 has a recess 100 formed thereon. The LED die 12 is disposed on the bottom of the recess 100, and electrodes 124 of the LED die 12 are electrically connected to connecting pieces 11 formed on the bottom of the recess 100. The fluorescent layer 14 includes light-transparent adhesive and phosphor powder uniformly suspended within the light-transparent adhesive. The fluorescent layer 14 is placed within the recess 100 and covers the LED die 12 for converting a part of light emitted from the LED die 12 into wavelength-converted light.

The LED 12 emits light in a blue spectrum and the fluorescent layer 14 absorbs some of the light in the blue spectrum and re-emits light in a yellow spectrum. The LED die 12 includes a top surface 120 and a lateral surface 122 adjacent to the top surface 120. Light emitted from the top surface 120 is transmitted to a direction opposite to the carrier 10 and is referred to as forward light, and light emitted from the lateral surface 122 is transmitted to left and right side of the carrier 10 and is referred to as side light. However, non-uniformity intensity and yellow-ring phenomenon occur since the intensity of the forward light is larger than that of the side light when sensing intensity of the illuminant component 1 from ahead of the illuminant device 1.

### SUMMARY OF THE INVENTION

Accordingly, the illuminant component according to one aspect of the present invention comprises a carrier, a plurality of connecting pieces, a light emitting diode (LED) die, a first fluorescent layer and a second fluorescent layer. The carrier comprises a die-bonding area; the connecting pieces are placed on the die-bonding area, and the LED die comprising a top surface is placed on the die-bonding area and electrically connected to the connecting pieces. The first fluorescent layer comprising a first light-transparent adhesive and a first phosphor powder uniformly suspended within the first light-transparent adhesive is placed on the top surface of the LED die, and the second fluorescent layer comprising a second light-transparent adhesive and a second phosphor powder uniformly suspended within the second light-transparent adhesive covers the first fluorescent layer and the LED die. In the same quantity of the first light-transparent adhesive and the second light-transparent adhesive, the quantity of the second phosphor powder is less than that of the first phosphor powder.

In an embodiment of the present invention, the first fluorescent layer comprises sixty (60) to one hundred and fifty (150) grams of the first phosphor powder for every hundred grams of the first light-transparent adhesive, and the second fluorescent layer comprises two (2) to twenty (20) grams of the second phosphor powder for every hundred grams of the second light-transparent adhesive. Moreover, the LED die emits light in a blue spectrum, and the first fluorescent layer and the second fluorescent layer absorb some of the light in the blue spectrum and re-emit light in a yellow spectrum, and an excitation spectrum of the second phosphor powder is similar to or the same as an excitation spectrum of the first phosphor powder.

The illuminant element can further comprise an optical lens placed on the second fluorescent layer, and a projected area of the optical lens projected on an upper surface of the carrier is larger than a projected area of the LED die projected on the upper surface.

The optical lens can comprises a convex portion and a flange portion extending from a peripheral region of the convex portion. A thickness of the flange portion is smaller that that of the convex portion, and a projected area of the convex portion projected on the upper surface is larger than a projected area of the LED dis projected on the upper surface.

The carrier can comprise a recess with a bottom wall and a sidewall formed on the die-bonding area, an included angle between the bottom wall and the sidewall is an obtuse angle, and the LED die is placed on the bottom wall.

The illuminant component further comprises a plurality of connecting pieces formed on the bottom wall, penetrating the carrier and extending to a lower surface of the carrier. The second fluorescent layer fills within a space between the bottom wall of the recess, the lower surface of the LED die, and the electrodes.

Furthermore, the illuminant component can comprises at least one wire connected to one of electrodes of the LED die and one of the connecting pieces.

The illuminant component according to the present invention placed the first fluorescent layer on the top surface of the LED die, so that light emitted from the top surface is absorbed by the first fluorescent layer at first, and then is absorbed by the second fluorescent layer. As the result, uniformity of the illuminant component can be improve and eliminate the occurrence of the yellow ring phenomenon.

### BRIEF DESCRIPTION OF DRAWINGS

FIG. 1 is a sectional view of a conventional light emitting diode.

FIG. 2 is a sectional view of a light emitting diode according to a first embodiment of the present invention.

FIG. 3 is a sectional view of a light emitting diode according to a second embodiment of the present invention.

FIG. 4 is a sectional view of a light emitting diode according to a third embodiment of the present invention.

FIG. 5 is a sectional view of a light emitting diode according to a fourth embodiment of the present invention.

FIG. 6 is sectional view of a light emitting diode according to a fifth embodiment of the present invention.

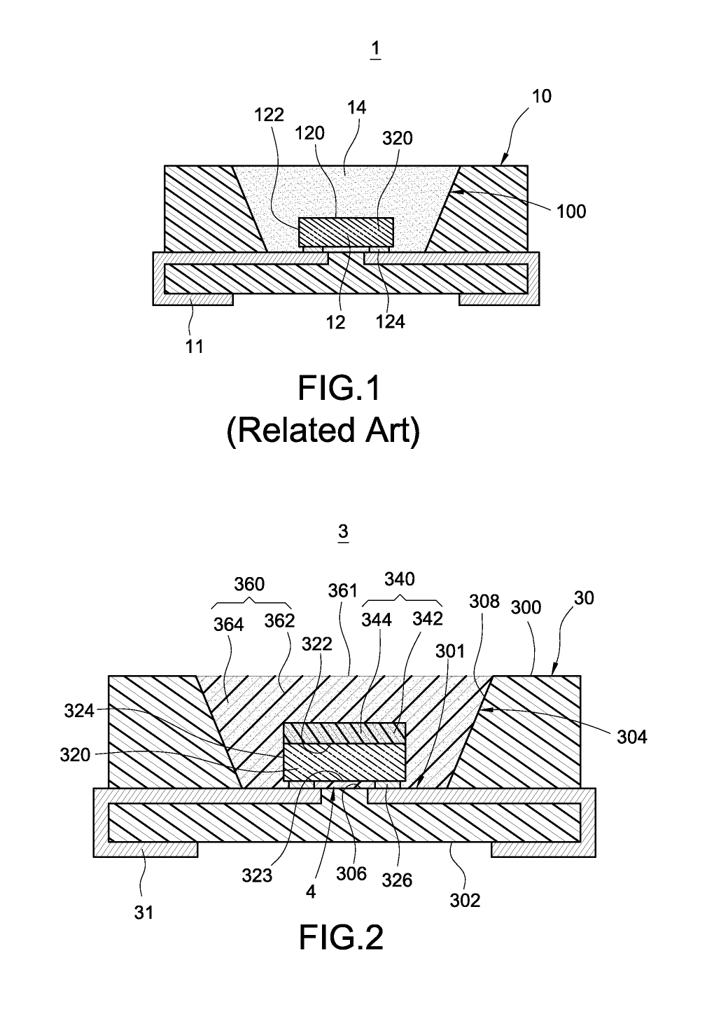

### DETAILED DESCRIPTION OF THE INVENTION

A preferred embodiment of the present invention will be described with reference to the drawings.

Reference is made to FIG. 2, which is a sectional view of an illuminant component according to a first embodiment of the present invention. The illuminant component 3 includes a carrier 30, a light emitting diode (LED) die 320, a first fluorescent layer 340, and a second fluorescent 360. The carrier 30 includes an upper surface 300 and a lower surface 302 opposite to the upper surface 300. In this embodiment, the upper surface 300 and the lower surface 302 are planes, and the lower surface 302 is parallel to the upper surface 300. The carrier 30 further includes a die-bonding area 301, and a recess 304 is formed on the die-bonding area 301. In particular, the recess 304 is formed on the upper surface 300 and concaved toward the lower surface 302. In a side profile of the carrier 30, the recess 302 has a bottom wall 306 and a sidewall 308. The bottom wall 308 is substantially parallel to the upper surface 300 (or the bottom surface 302), the sidewall 308 is adjacent to the bottom wall 306 and an included angle between the sidewall 308 and the bottom wall 306 is an obtuse angle.

The illuminant component 3 further includes a plurality of connecting pieces 31, the connecting pieces 31 dispose on bottom wall 304 of the recess 304 penetrate the carrier 30 and extend to the lower surface 302 of the carrier 30. The connecting pieces 31 are made of electrically conductive material, such as copper, for conducting electric power to the LED die 32.

The LED die 32 is placed within the recess 304 and electrically connected to the connecting pieces 31. The LED die 32 includes a top surface 322, a bottom surface 322 opposite to the top surface 322, and a lateral surface 324 adjacent to the top surface 322 and the bottom surface 324. In this embodiment, the illuminant component 3 has only one LED die 320, and the LED die 320 is a flip-chip LED die, so that the electrodes 326 of the LED die 320 are formed on the bottom surface 323 thereof, and can electrically connect to the connecting pieces 31 directly. In the practical application, the illuminant component 3 can include more than one LED dies 320, and the LED dies 320 may be horizontal structure LED dies or perpendicular structure LED dies.

The first fluorescent layer 340 is placed on the top surface 322 of the LED die 320 and fully covers the top surface 322. The first fluorescent layer 340 includes a first light-transparent adhesive 340 and a first phosphor powder 342 uniformly suspended within the first light-transparent adhesive 340. The light-transparent adhesive 340 is, for example, epoxy or silicone resin, and allowing light emitted from the LED die 320 passing therethrough. In the present invention, the first fluorescent layer 34 includes sixty (60) to one hundred and fifty (150) grams of the first phosphor powder 342 for every hundred grams of the first light-transparent adhesive 340.

The second fluorescent layer 360 fills within the recess 304, and covers the LED die 320 and the first fluorescent layer 340. The second fluorescent layer 360 has a filling surface 361 coplanar with the upper surface 302 of the carrier 30. The second fluorescent layer 360 also fills with a space 4 between the bottom wall 306 of the recess 304, the lower surface 323 of the LED die 320, and the electrodes 326. The second fluorescent layer 360 includes a second light-transparent adhesive 362 and second phosphor powder 364 suspended within the second light-transparent adhesive 362. The second light-transparent adhesive 362 is, for example, epoxy or silicone resin. The second light-transparent adhesive 362 is the same as the first light-transparent adhesive 342 such that the adhesive strength can be enhanced. However, in the practical application, the second light-transparent adhesive 362 may be different from the first light-transparent adhesive 342. In the present invention, the second fluorescent layer 360 includes two (2) to twenty (20) grams of the second phosphor powder 364 for every hundred grams of the second light-transparent adhesive 362.

During operation of the illuminant component 3, the first fluorescent layer 340 is placed on the top surface 322 of the LED die 320, and the second fluorescent layer 360 is filled within the recess 304 to cover the LED die 320 and the first fluorescent 340 as well as to fill the space 4 after the first fluorescent layer 340 is cured, and then the second fluorescent 360 is cured.

In this embodiment, the LED die 320 emits light in a blue spectrum, the first phosphor powder 344 and the second phosphor powder 362 absorb some of the light in the blue spectrum and re-emit light in a yellow spectrum. Not only the top surface 320 but also the lateral surface 324 of the LED die 320 can output light, and intensity of the forward light outputted from the top surface 322 is higher than intensity of side light outputted from the lateral surface 324, which causes the illuminant component 3 has poor light uniformity. In order to overcome the problem mentioned above, the quantity of the first phosphor powder 344 added to the first light-transparent adhesive 342 is more than the quantity of the second phosphor powder 362 added to the second light-transparent adhesive 362 having the same quantity as the first light-transparent adhesive 342. Since the first phosphor powder 344 absorbs some of the light in the blue spectrum and re-emits light in a yellow spectrum, as the quantity of the first phosphor powder 344 is more, the intensity of forward light outputted from the top surface 322 is reduced, and then light uniformity of the illuminant device 3 can be improved. It is be noted that the illuminant component 3 of the present invention is not limited to emit light in a white spectrum, and the excitation spectrum of the first phosphor powder 344 and the second powder 364 can also be adjusted to generate illuminant component emits light in other spectrum.

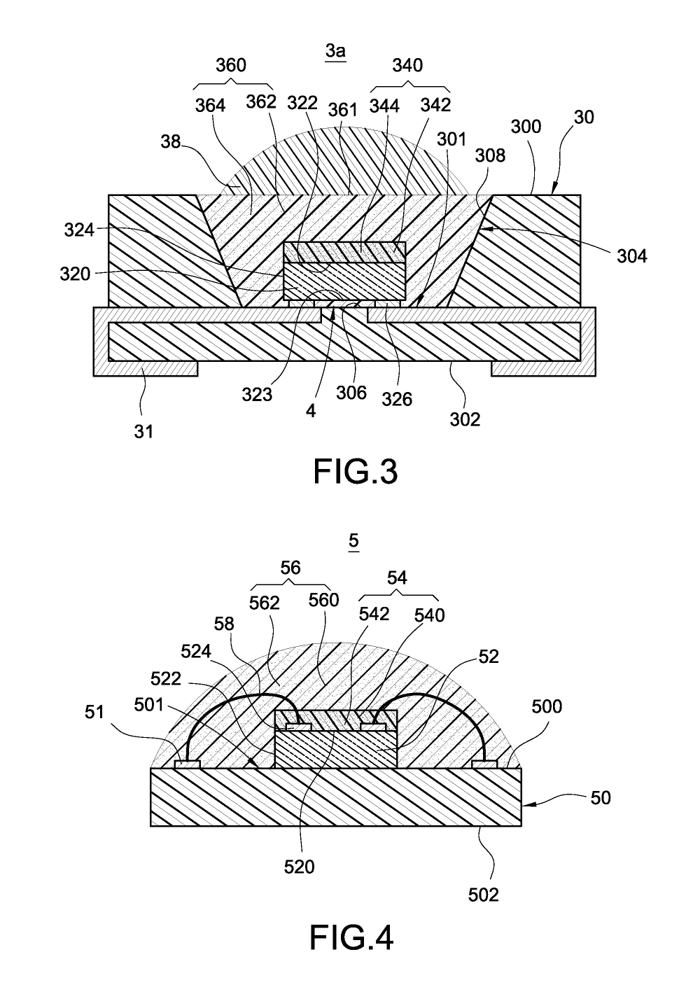

Reference is made to FIG. 3, which is a sectional view of an illuminant component according to a second embodiment of the present invention. The illuminant component 3a shown in FIG. 3 is similar to the illuminant component 3 mentioned in the first embodiment, and the same reference numbers are used in the drawing and the description to refer to the same parts. It should be noted that the illuminant component 3a further includes an optical lens 38.

The optical lens 38 is placed on the second fluorescent layer 360 and corresponding to the LED die 320. In this embodiment, the optical lens 38 covers the second fluorescent layer 360 and a projected area of the optical lens 38 projected on the upper surface 300 of the carrier 30 is larger than a projected area of the LED die 320 projected on the upper surface 300. The optical lens 38 is made of glass, silicone resin, or epoxy, and configured to refract light passing therethrough. The function and related description of other elements of the illuminant component 3a are the same as that of first embodiment mentioned above and they are not repeated here, and the illuminant component 3a can achieve the function as the illuminant device 3 does.

Reference is made to FIG. 4, which is a sectional view of an illuminant component according to a third embodiment of the present invention. The illuminant component 5 includes a carrier 50, a light emitting diode (LED) die, a first fluorescent layer 54, and a second fluorescent layer 56. The carrier 50 includes an upper surface 500 and a lower surface 502 opposite to the upper surface 500 and parallel to the upper surface 500. The carrier 50 has a profile of plate shape. At least one connecting piece 51 made of electrically conductive material, such as copper, is formed on the upper surface 500 of the carrier 50. The carrier 50 further includes a die-bonding area 501.

The LED die 52 is placed on the die-bonding area 501 and includes a top surface 520, a lateral surface 522 adjacent to the top surface 520, and at least one electrode 524. In this embodiment, the LED die 52 is horizontal structure LED die and includes two electrodes 524 placed on the top surface 520 thereof. However, in the practical applications, the LED die 52 may be vertical structure LED die and two electrodes 524 thereof are respectively placed on the top surface 520 and a bottom surface opposite to the top surface 520.

The illuminant component 5 further includes at least one wire 58, one end of the wire 58 is connected to the electrode 524, and the other end is connected to the connecting piece 51 for electrically connecting the LED die 52 and the connecting piece 51. In this embodiment, the illuminant component 5 includes two wires 58, one end of each wire 58 is connected to the electrodes 524 of the LED die 52, and the other end of each wire 58 is connected to the connecting piece 51 formed on the carrier 50. It should be noted that when the LED die 52 is a vertical structure LED die, one of two electrodes is contact with the one of the connecting pieces, and the other electrodes is electrically connected to the other connecting piece via a wire.

The first fluorescent layer 54 is placed on the top surface 520 of the LED die 52. The first fluorescent layer 54 fully convers the top surface 520 and partially convers the electrodes 524 and wires 58. The first fluorescent layer 54 includes first light-transparent adhesive 540 and a first phosphor powder 542 uniformly suspended within the first light-transparent adhesive 540. The first light-transparent adhesive 540 is, for example, epoxy or silicone resin. In this embodiment, the first fluorescent layer 54 includes sixty (60) to one hundred and fifty (150) grams of phosphor powder 542 for every hundred grams of the first light-transparent adhesive 540.

The second fluorescent layer 56 covers the LED die 52, the first fluorescent layer 54, and the wires 58, and has an arc profile for enlarging light emitting angle. The second fluorescent layer 56 includes a second light-transparent adhesive 560 and a second phosphor powder 562 uniformly suspended within the second light-transparent adhesive 560. The second light-transparent adhesive 560 is, for example, epoxy or silicone resin, and the second light-transparent adhesive 560 may be the same as or different from the first light-transparent adhesive 540. In this embodiment, the second fluorescent layer 56 includes two (2) to twenty (20) grams of phosphor powder 562 for every hundred grams of the second light-transparent adhesive 560.

In this embodiment, the LED die 52 emits light in a blue spectrum, the first fluorescent layer 54 absorbs some of the light in the blue spectrum and re-emits light in a yellow spectrum, and the second fluorescent layer 56 also absorbs some of the light in the blue spectrum and re-emits light in a yellow spectrum. In addition, an excitation spectrum of the second phosphor powder 562 is similar to or the same as an excitation spectrum of the first phosphor powder 542. In the same quantity of the first light-transparent adhesive 540 and the second light-transparent adhesive 562, the quantity of the second phosphor powder 562 is less than that of the first phosphor powder 542, intensity of the forward light outputted form the top surface 520 of the LED die 53 can be reduce. Therefore, the light uniformity of the illuminant component 5 can be effectively improved.

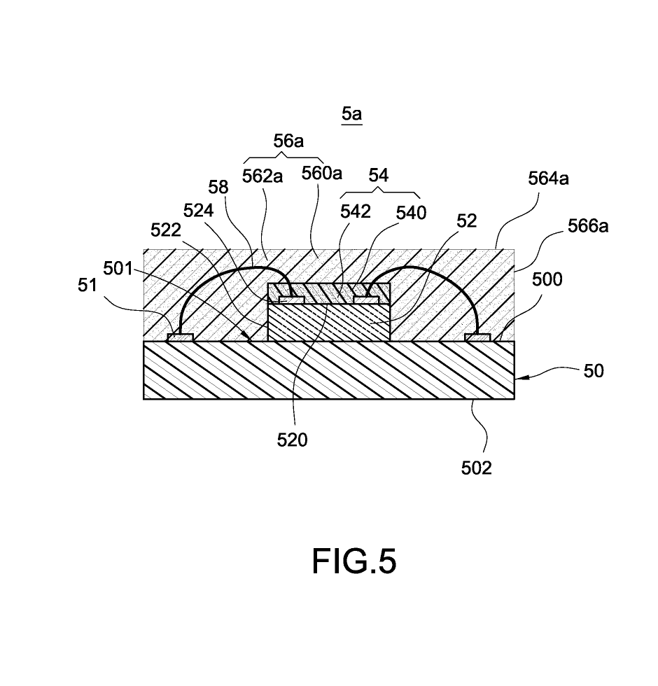

Reference is made to FIG. 5, which is a sectional view of an illuminant component according to a fourth embodiment of the present invention. The illuminant component 5a shown in FIG. 5 is similar to the illuminant component 5 mentioned in the third embodiment, and the same reference numbers are used in the drawing and the description to refer to the same parts. It should be noted that a portion of the second fluorescent layer 56a of the illuminant component 5a is different from that of in the third embodiment.

The second fluorescent layer 56a covers the LED die 52, the first fluorescent layer 54, and the wires 58. The second fluorescent layer 56a includes a second light-transparent adhesive 560a and second phosphor powder 562a uniformly suspended within the second light-transparent adhesive 560a. The second light-transparent adhesive 560a is, for example, epoxy or silicone resin. The second light-transparent adhesive 560a is the same as the first light-transparent adhesive 540a or different from the first light-transparent adhesive 540.

A top surface 564a of the second fluorescent layer 56a is a plane and substantially parallel to the upper surface 500, and a side surface 566a is a plane and substantially perpendicular to the upper surface 500, and a profile of the illuminant component 5a is substantially of rectangular. The function and related description of other elements of the illuminant component 5a are the same as that of first embodiment mentioned above and they are not repeated here, and the illuminant component 5a can achieve the function as the illuminant device 5 does.

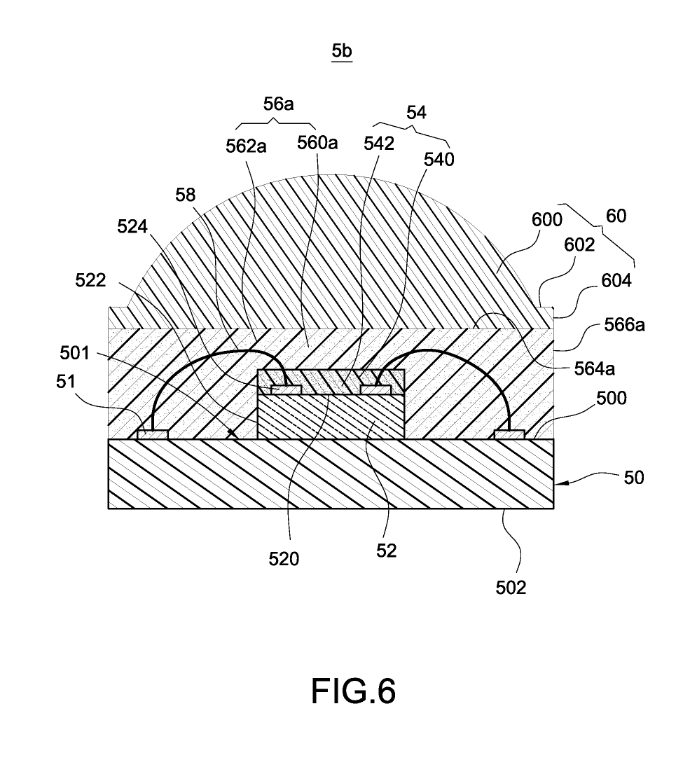

Reference is made to FIG. 6, which is a sectional view of an illuminant component according to a fifth embodiment of the present invention. The illuminant component 5b shown in FIG. 6 is similar to the illuminant component 5a mentioned in the fourth embodiment, and the same reference numbers are used in the drawing and the description to refer to the same parts. It should be noted that the illuminant component 5b further includes an optical lens 60.

The optical lens 60 is made of glass, silicone resin, or epoxy, and configured to refract light passing therethrough. The optical lens 60 includes a convex portion 600 and a flange portion 602, the convex portion 600 forms a position lens for adjusting light emitted from the LED die 52. A projected area of the convex portion 600 projected on the upper surface 500 of the carrier 50 is larger than a projected area of the LED die 52 projected on the upper surface 500 of the carrier 50. The flange portion 602 extends from a peripheral region of the convex portion 600, a thickness of the flange portion 602 is smaller than a thickness of the convex portion 600, and an edge 604 of the flange portion 602 is aligned with the side surface 566a of the second fluorescent layer 56a. The function and related description of other elements of the illuminant component 5b are the same as that of first embodiment mentioned above and they are not repeated here, and the illuminant component 5b can achieve the function as the illuminant device 5a does.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

1. An illuminant component, comprising:
a carrier comprising a die-bonding area;
a plurality of connecting pieces placed on the die-bonding area;
a light emitting diode (LED) die comprising a top surface, the LED die placed on the die-bonding area and electrically connected to the connecting pieces;
a first fluorescent layer comprising a first light-transparent adhesive and a first phosphor powder suspended within the first light-transparent adhesive, the first fluorescent layer placed on the top surface of the LED die;
a second fluorescent layer comprising a second light-transparent adhesive and a second phosphor powder suspended within the second light-transparent adhesive, the second fluorescent layer covering the first fluorescent layer and the LED die; and
an optical lens disposed on the second fluorescent layer so that a filling surface of the second fluorescent layer is partially covered by the optical lens, a projected area of the optical lens projected on an upper surface of the carrier being larger than that of the LED die projected on the upper surface;
wherein in the same quantity of the first light-transparent adhesive and the second light-transparent adhesive, the quantity of the second phosphor powder is less than that of the first phosphor powder.

2. The illuminant component in claim 1, wherein the first fluorescent layer comprises sixty (60) to one hundred and fifty (150) grams of the first phosphor powder for every hundred grams of the first light-transparent adhesive, and the second fluorescent layer comprises two (2) to twenty (20) grams of the second phosphor powder for every hundred grams of the second light-transparent adhesive.

3. The illuminant component in claim 1, wherein the first fluorescent layer fully covers the top surface of the LED die.

4. The illuminant component in claim 3, wherein an excitation spectrum of the second phosphor powder is similar to or the same as an excitation spectrum of the first phosphor powder.

5. The illuminant component in claim 4, wherein the LED die emits light in a blue spectrum, and the first fluorescent layer and the second fluorescent layer absorb some of the light in the blue spectrum and re-emit light in a yellow spectrum.

6-7. (canceled)

8. The illuminant component in claim 1, further comprising at least one wire connected to one of electrodes of the LED die and one of the connecting pieces.

9. The illuminant component in claim 5, wherein the carrier further comprises a recess with a bottom wall and a sidewall adjacent to the bottom wall formed on the die-bonding area, the LED die is placed on the bottom wall, and the connecting pieces are formed on the bottom wall, penetrating the carrier and extending to a lower surface of the carrier.

10. The illuminant component in claim 9, wherein the second fluorescent layer fills within a space between the bottom wall of the recess, the lower surface of the LED die, and the electrodes.

11. The illuminant component in claim 2, wherein the first fluorescent layer fully covers the top surface of the LED die.

12. The illuminant component in claim 11, wherein an excitation spectrum of the second phosphor powder is similar to or the same as an excitation spectrum of the first phosphor powder.

13. The illuminant component in claim 12, wherein the LED die emits light in a blue spectrum, and the first fluorescent layer and the second fluorescent layer absorbs some of the light in the blue spectrum and re-emit light in a yellow spectrum.

14. (canceled)

15. The illuminant component in claim 13, further comprising an optical lens having a convex portion and a flange portion extending from a peripheral region of the convex portion, a thickness of the flange portion is smaller than a thickness of the convex portion, and a projected area of the convex projected on the upper surface of the carrier is larger than the projected area of the LED dis projected on the upper surface.

16. The illuminant component in claim 15, further comprising at least one wire connected to one of electrodes of the LED die and one of the connecting pieces.

17. The illuminant component in claim 13, wherein the carrier further comprises a recess formed on the die-bonding area, the recess has a bottom wall and a sidewall adjacent to the bottom wall, the LED die is placed on the bottom wall, and the connecting pieces are formed on the bottom wall, penetrating the carrier and extending to a lower surface of the carrier.

18. The illuminant component in claim 17, wherein the second fluorescent layer fills within a space between the bottom wall of the recess, the lower surface of the LED die, and the electrodes.
